(19) United States
(12) Patent Application Publication
(10) Pub. No.: US 2022/0215308 A1
(43) Pub. Date: Jul. 7, 2022

(54) PREDICTING RESERVOIR COMPOSITION FROM MUDGAS LOGS

(71) Applicant: Saudi Arabian Oil Company, Dhahran (SA)

(72) Inventor: Anuj Gupta, Katy, TX (US)

(21) Appl. No.: 17/644,233

(22) Filed: Dec. 14, 2021

Related U.S. Application Data
(60) Provisional application No. 63/133,457, filed on Jan. 4, 2021.

(51) Int. Cl. G06Q 10/06; E21B 49/00; G06N 5/02; G06F 16/18; G01V 11/00; G01V 99/00

(52) U.S. Cl. CPC G06Q 10/0637; E21B 49/00; G06N 5/02; E21B 2200/20; G01V 11/002; G01V 99/005; G06F 16/1805

(57) ABSTRACT

A method and a system for predicting hydrocarbon composition of a reservoir fluid from mud log data are provided. An exemplary method includes generating predictors from an analysis of a database of mud log data, generating predicted mole fractions of a hexane fraction and a heptane+ fraction using the predictors, generating a predicted molecular weight of the heptane+ fraction, and predicting mole fractions of hydrocarbons representing the hydrocarbon composition of the reservoir fluid. The hydrocarbon composition, the predicted molecular weight, the predicted mole fractions or the predictors, or any combinations thereof, are displayed.

### CLAIM OF PRIORITY

This application claims priority to U.S. Provisional Application Ser. No. 63/133,457, filed on Jan. 4, 2021, the entire contents of which is hereby incorporated by reference.

### TECHNICAL FIELD

The present disclosure is directed to using composition data from mudgas logs to predict the composition of oil or gas in subsurface reservoirs.

### BACKGROUND

A detailed composition of oil or gas present in a subsurface reservoir is needed to accurately calculate the amount of oil and gas in the reservoir, expected viscosity, density, API gravity of oil, Gas-Oil-Ratio/Condensate-Gas-Ratio and other characteristics needed for design of primary and enhanced recovery processes and surface facilities.

One method for determining reservoir composition is to acquire reservoir fluid samples before the well is put on production using a fluid sampler on a wireline cable. However, this process takes valuable rig-time and entails significant cost. Further, wireline fluid sampling does not work well for shale oil and gas reservoirs, due to the low mobility of reservoir fluids in these reservoirs. Even when a fluid sample is collected, the composition is often different due to the loss of smaller molecules, such as methane and ethane, from the sample.

An alternative to wireline fluid samples for obtaining reservoir fluid samples is to collect produced oil and gas samples from surface production facilities, for example, after the well is placed on production and recombine the samples in the correct proportions to reconstitute the original reservoir fluid. However, it is difficult to recombine the produced oil and gas in correct proportions to simulate the reservoir fluids. Generally, the composition of the produced fluid is often different from the original reservoir fluid, especially in reservoirs with very low permeability, such as shale reservoirs. Finally, since production samples can only be collected after the well starts producing, the properties of reservoir fluids needed for well completion optimization and design of surface facilities are not available in a timely manner.

### SUMMARY

An embodiment described in examples herein provides a method for predicting hydrocarbon composition of a reservoir fluid from mud log data. The method includes generating predictors from an analysis of a database of mud log data, generating predicted mole fractions of a hexane fraction and a heptane+ fraction using the predictors, generating a predicted molecular weight of the heptane+ fraction; and predicting mole fractions of hydrocarbons representing the hydrocarbon composition of the reservoir fluid. The hydrocarbon composition, the predicted molecular weight, the predicted mole fractions or the predictors, or any combinations thereof, are displayed.

Another embodiment described in examples herein provides a system for predicting hydrocarbon composition of a reservoir fluid from mud log data. The system includes a processor and a datastore. The data store includes, a composition database, and a regression engine including instructions that, when executed, direct the processor to analyze the composition database to generate predictors. The data store also includes a predictor store including predictors generated by the regression engine, and a prediction calculator including instructions that, when executed, direct the processor to generate composition predictions. The system includes an output device to provide the predictors, the composition predictions, or both to a user.

### BRIEF DESCRIPTION OF DRAWINGS

FIG. 1 is an example plot of a mudgas log collected during the drilling of a wellbore

FIG. 2A is a process flow diagram of a method for calculating reservoir fluid composition from mud log analyses and using it in reservoir simulator.

FIG. 2B is a simplified process flow diagram of the method for calculating the reservoir fluid composition from the mud log analyses.

FIG. 3 is a block diagram of a system that may be used for predicting a reservoir composition and properties from mudgas logs.

FIG. 4 is a plot of the prediction of the mole fraction of hexane from mud log data.

FIG. 5 is a plot of the prediction of the mole fraction of heptane+ from mud log data.

FIG. 6 is a plot of the prediction of the apparent molecular weight of heptane+ from mud log data.

### DETAILED DESCRIPTION

As described herein, the detailed composition of oil or gas present in a subsurface reservoir is needed to accurately calculate the amount of oil and gas in the reservoir, as well as other properties, such as the expected density, viscosity, API gravity of oil, expected Gas-Oil-Ratio (GOR)/Condensate-Gas-Ratio (CGR) and other characteristics needed for design of surface facilities and primary and enhanced recovery processes. The composition is often expressed as the mole-fractions or percentages of various components, such as methane, ethane, propane, butane, pentane, hexane, and heptane+. As used herein, heptane+ includes all heptane isomers and larger molecules. Similarly, as used herein, propane, butane, pentane, and hexane include all isomers thereof.

If fluid samples are collected, through wireline or production sampling, they can be analyzed to determine the composition. Further, laboratory tests may be conducted to measure properties of interest, such as oil density, viscosity, compressibility, and gas-oil-ratio (GOR) or Condensate-Gas-Ratio (CGR). The measured fluid composition can be used along with thermodynamic models, termed “equations-of-state,” to calculate detailed phase-envelopes, which may be used to calculate reservoir fluid properties at any combination of pressure and temperature conditions.

Attempts have been made to utilize mudgas logs to determine properties, such as gas-oil-ratio (GOR). Studies have used databases of oil properties collected by service companies to attempt to estimate a bubble point pressure. As used herein, the bubble point pressure is the pressure at which the first bubble of gas appears as the pressure is lowered. Certain correlations, for bubble point pressure and other fluid properties, require use of stock-tank gas rate and specific gravity. Since these data are seldom measured in the field, additional correlations are required from data usually only available in field operations. The correlations may also be useful for estimating stock-tank vent gas rate and quality for compliance purposes.

However, none of the available methods have attempted to determine the overall composition of the reservoir fluid, for example, in mole-fractions of various hydrocarbon components. Embodiments described herein provide a method of using the gas compositions recorded during mudgas logging to predict the full composition of the reservoir petroleum fluid.

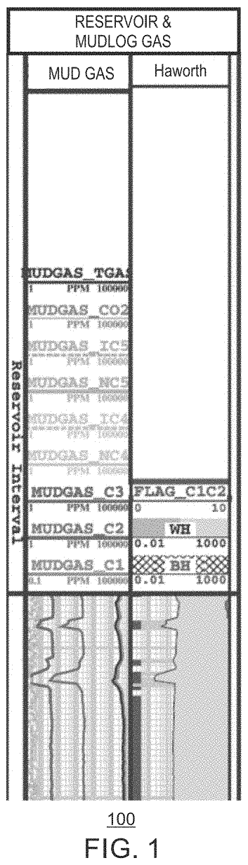

FIG. 1 is an example plot 100 of a mudgas log collected during the drilling of a wellbore. The drilling fluids returned to the surface are analyzed, for example, by gas chromatography or other techniques, and the content of hydrocarbons are recorded, including, for example, methane, ethane, propane, iso-butane, n-butane, iso-pentane, and n-pentane. The plot 100 records concentration of various gas molecules in parts-per-million (PPM). For example, it reports PPM of C1 (methane), C2 (ethane), C3 (propane), NC4 (normal-butane), IC4 (isobutane), NC5 (normal pentane), IC5 (isopentane), CO2 (carbon dioxide) and TGAS (total gas).

The ratio of the concentration for each molecule to total gas concentration is calculated as an input for predictor equations to calculate the needed mole fractions and molecular weights. Mudgas logs plot amounts of various molecules at each depth intersected by a well. The composition data is averaged for each reservoir depth interval of interest to get input for reservoir fluid representing the reservoir interval of interest, as indicated by a depth range.

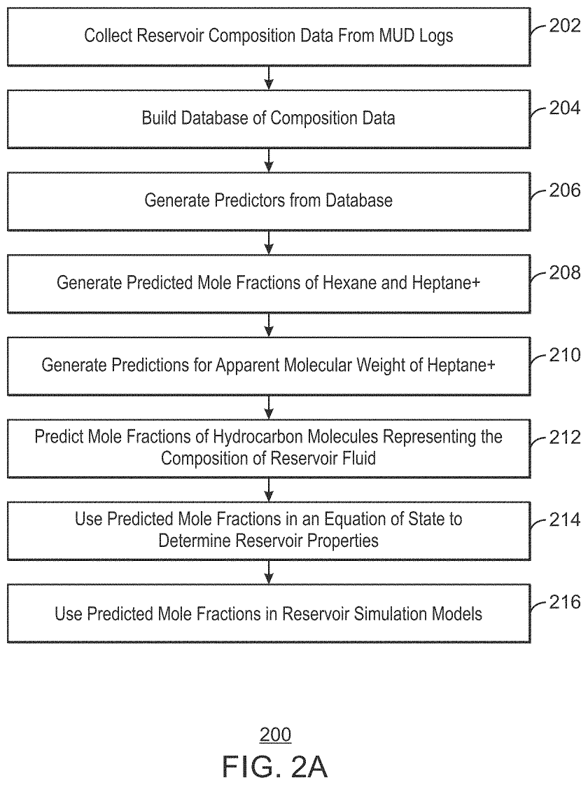

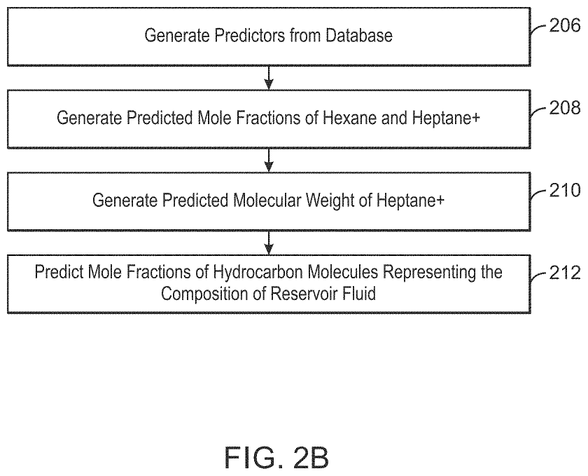

FIG. 2A is a process flow diagram of a method 200 for predicting oil and gas composition from mudgas logs for depth interval of interest representing the reservoir from which the fluid is produced. The method 200 begins at block 202 with the collection of composition data from mud logs. At block 204, the composition data is used to build a database of petroleum fluid compositions is built for oil and gas samples from similar reservoirs. At block 206, the database is processed through a non-parametric regression engine, for example, using an iterative procedure based on an alternating conditional expression (ACE) method, implemented as a computer program, to generate predictors for mole fractions of hexane and heptane+ and apparent molecular weight of heptane+ based on relative concentration of methane, ethane, propane, butane and pentane recorded in mudgas logs. The ACE regression engine doesn't require a priori assumption of a function form and the optimal transformations are obtained only based on the database of reservoir fluid compositions.

The ACE method was originally proposed as a method for estimating optimal transformations for multi-variable regression that results in maximum correlation between a dependent variable and multiple independent variables. In this method, the dependent variable, which is the target of the prediction, is transformed using a mathematical transformation by the computer program. Similarly, each independent variable is mathematically transformed by the computer program. The coefficients of each transformation equation for the independent variable are adjusted by the computer program to achieve optimal correlation with the transformed dependent variable. The coefficients of transformation function for dependent variable are also adjusted to achieve optimal correlation with the weighted sum of transformed dependent variable. A weighted sum of the transformed independent variables is used as a “predictor” of the dependent variable of interest. The transformation function are non-parametric when physical functions are not available. However, if physical relationship between dependent variable and independent variable is known, the mathematical form of such physical laws is usable in the computer program to guide the process of developing the predictor functions. The database of composition of petroleum samples from reservoirs with compositional similarity to target reservoir are used as the basis of generating predictor equations by the computer program. Mole fractions of methane, ethane, propane, butanes, pentanes, hexanes and heptane-plus and apparent molecular weight of heptane-plus pseudo-component for all fluid compositions in the database are processed through the ACE computer program to generate transformed functions that contribute to creation of predictors for mole fractions of hexane and heptane-plus and apparent molecular weight of heptane-plus pseudo component.

At block 208, the predictors are used to generate predicted mole fractions of hexane and heptane+ based on fraction of measured hydrocarbon components by the mud-gas logs. At block 210, the predictors are used to generate predictions for the apparent molecular weight of heptane+ based on fraction of measured hydrocarbon components by the mud-gas logs. At block 212, predictions are used to generate predicted mole fractions of the hydrocarbon molecules commonly used to represent the composition of a reservoir fluid (oil or gas). In an embodiment, the predicted mole fractions include methane, ethane, propane, iso-butane, n-butane, iso-pentane and n-pentane, hexane and heptane+. The apparent molecular weight of heptane+ is used with these predicted values to describe the composition of an oil or gas. As described herein, heptane+represents all molecules including heptane, its isomers, and larger molecules. Therefore the apparent molecular weight depends of relative amounts of larger molecules.

In various embodiments, the mudgas logs record different hydrocarbon components. Accordingly, in these embodiments, the predictions are adapted for the amounts of the actual components recorded. For example, in some compositional analyses, more detailed mole fractions may be reported as shown in Table 1. In Table 1, C₁₂H₂₆₊ refers to amounts of molecules including dodecane and larger and f₁₂₊ refers to the mole fraction of all such molecules. More frequently, heptane and larger molecules are lumped together as C7+(heptane+) and the amounts of molecules including heptane and larger are represented by the mole fraction f₇. These representation of the composition of petroleum reservoir fluids is illustrated in Table 2.

At block 214, the composition of the reservoir fluid is used in an equation of state to determine other reservoir properties of interest, such as bubble-point pressure and gas-oil-ratio for oil reservoirs, and dew-point pressure and condensate-gas-ratio for gas reservoirs. Additionally, fluid compressibility, viscosity, fluid density API gravity of produced oil and specific gravity of produced gas can be calculated.

The full composition as calculated in Table 4, when used along with Equation of State, such as the Peng-Robinson equation of state or any other suitable equation of state known in the art, is sufficient to calculate other reservoir properties of interest such as the API gravity of oil, a Gas-Oil-Ratio, or a Condensate-Gas-Ratio. Such equations of state for hydrocarbon fluid mixtures are integrated into commercial reservoir simulation software, such as available from CMG, Schlumberger, Halliburton, etc., for calculating other characteristics of the reservoir fluids that are needed for the design of surface facilities, and primary and enhanced recovery processes. The simulation packages that are commercially available include CMG-WINPROP, PVTSIM and REFPROP (National Institute of Standards and Testing), among others. Examples of these fluid characteristics include Gas-oil-Ratio, Condensate-Gas-Ratio, API gravity of oil, specific gravity of produced gas, etc.

At block 216, the predicted mole fractions are used in reservoir simulation models to predict properties for the reservoir, including, for example, future production, expected ultimate recovery, and potential additional oil recovery using enhanced oil recovery (EOR) methods, among others.

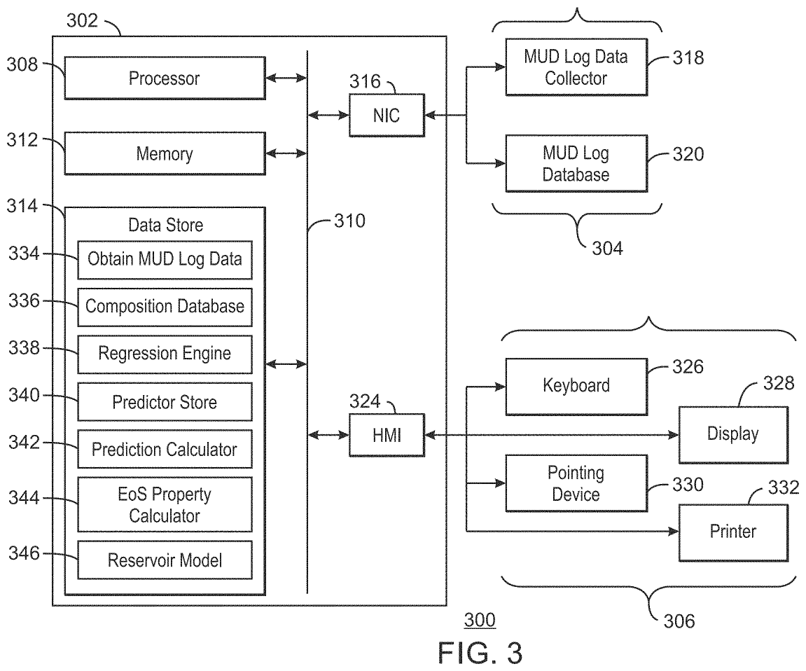

In various embodiments, the system displays the results of each of the blocks 206-216. The display may be provided on a monitor, or may be part of a printout included in a printed report of the results, or both. This is described further with respect to FIG. 3.

FIG. 2B is a simplified process flow diagram of the method 200 for modeling the reservoir composition from the mud log analyses. Like numbered items are as described with respect to FIG. 2A. Not all of the actions shown in FIG. 2A are used in every embodiment. In some embodiments, the mole fractions of hydrocarbon molecules representing the composition of the reservoir fluid, as calculated in block 212, are used for other purposes. For example, in some embodiments, the composition predictions are used for designing well completions, geosteering in directional drilling, or designing surface facilities.

FIG. 3 is a block diagram of a system 300 that may be used for predicting a reservoir composition and properties from mudgas logs. The system 300 includes a calculation system 302, data sources 304, and I/O devices 306. In various embodiments, the calculation system 302 is a desktop computer, a tablet computer, a distributed control system, a cloud computing system, or a combination thereof.

The calculation system 302 includes a processor 308. The processor 308 may be a microprocessor, a multi-core processor, a multithreaded processor, or a virtual processor, among others. In various embodiments, the processor 308 includes processors from Intel® Corporation of Santa Clara, Calif., from Advanced Micro Devices, Inc.

(AMD) of Sunnyvale, Calif., or from ARM Holdings, LTD., Of Cambridge, England. Any number of other processors from other suppliers may also be used. In some embodiments, the processor 308 is a virtual processor, for example, in a cloud computing system.

The processor 308 communicates with other components of the calculation system 302 over a bus 310. In various embodiments, the bus 310 includes an industry standard architecture (ISA), an extended ISA (EISA), a peripheral component interconnect (PCI), a peripheral component interconnect extended (PCIx), or a PCI express (PCIe), among others. Other bus technologies may be used, in addition to, or instead of, the technologies above. For example, if the calculation system 302 is part of a process control system, the bus 310 may include Fieldbus or other technologies.

The bus 310 couples the processor 308 to a memory 312. In some embodiments, the memory 312 is integrated with a data store 314 used for long-term storage of programs and data. In various embodiments, the memory 312 includes any number of volatile or nonvolatile memory devices, such as volatile random-access memory (RAM), static random-access memory (SRAM), flash memory, and the like.

The data store 314 is used for the persistent storage of information, such as data, applications, operating systems, and so forth. The data store 314 may be a nonvolatile RAM, a solid-state disk drive, or a flash drive, among others. In some embodiments, the data store 314 will include a hard disk drive, such as a micro hard disk drive, a regular hard disk drive, or an array of disk drives, for example, associated with a distributed control system (DCS) or a cloud server.

The bus 310 couples the processor 308 to a network interface controller (NIC) 316. In various embodiments, the NIC 316 couples the calculation system 302 to the data sources 304 for retrieval of the composition data from mud logs. In some embodiments, the NIC 316 is an Ethernet interface used to couple to the data sources 304 over an internal network, an external network, or the Internet. The data sources include, for example, a mud log data collection system 318, or a mud log database 320, or both. The mud log data collection system 318 may be a control system on a platform or drilling rig that collects data from sensors and mud logging tools. The mud log database 320 may be a commercial database storing information from a number of producers, service companies, and the like, or may be a proprietary database, for example, including data from a single company's hydrocarbon fields.

In some embodiments, the bus 310 couples the processor 308 to a human-machine interface (HMI) 324. The HMI 324 couples the calculation system 302 to a number of I/O devices 306 used to control the calculation system 302 and to provide outputs from the calculation system 302. In various embodiments, the I/O devices 306 include a keyboard 326, a display 328, a pointing device 330, or a printer 332, or any combinations thereof. The display 328 may be a monitor or a projector, among others. The display 328 and the printer 332 allow for the information from the analysis to be provided to a user, for example, allowing its use for adjustments to drilling direction, design of completions, downstream equipment, and the like.

The data store 314 includes blocks of stored instructions that, when executed, direct the processor 308 to implement the functions of the calculation system 302. The data store 314 includes a block 334 of instructions to direct the processor 308 to obtain mud log data on hydrocarbon composition, for example, from the mud log data collection system 318, the mud log database 320, or both. In various embodiments this is performed, for example, by accessing the data sources 304 through the NIC 316.

In some embodiments, the data store 314 includes a composition database 336 generated from the information obtained from the data sources 304, for example, by the instructions of block 334. The composition database 336 may include the data needed for a reservoir analyses of data from a single well, or may be a broader data store, for example, including data for multiple wells over the reservoir, data for multiple reservoirs in a field, or a broad database of multiple fields. In embodiments in which the composition database 336 includes a broader data store, the calculation system 302 may function as a mud log database for other calculation systems.

The data store 314 also includes a block 338 of instructions to direct the processor 308 to perform a regression on the information stored in the composition database 336. For example, the block 338 may include a nonparametric regression engine, or other mathematical analyses, such as systems based on Bayesian analysis, neural networks, and the like.

The data store 314 as includes a predictor store 340 to store equations, and other predictors, generated by the instructions of the regression engine of block 338. The data store 314 also includes a block 342 of instructions to direct the processor 308 to use the equations of the predictor store 340 to calculate composition predictions for the reservoir. In some embodiments, the data store 314 includes a block 344 of instructions to direct the processor 308 to perform property calculations based on one or more equation of states. In some embodiments, the data store 314 includes a block 346 of instructions that function as a reservoir model to predict reservoir properties from the composition predictions, the equation of state predictions, or both.

### EXAMPLES

The average amounts of various hydrocarbon molecules recorded across a reservoir interval from a mudgas log were normalized to obtain the relative amounts of various molecules (as fractions) are listed in Table 3. It can be observed that data from mudgas logs do not include the relative amounts of hexane and heptane+, which are needed for use along with equation of state to calculate important reservoir properties. Thus the data in the mudgas logs includes the compositions of methane, ethane, propane, butane, and pentane.

A database of compositions of many reservoir oil/gas samples from similar reservoirs is prepared to obtain relationship between mole fractions of various components. Generally, the database will include at least 20 different compositional samples to be statistically significant. The databased is compiled in a tabular format, similar to table 1 or 2. Data for the database can be sourced from multiple resources. For specific applications, laboratory compositional analysis reports from various petroleum samples collected from wells in the area of interest provide the necessary data, for example, available from proprietary databases for specific fields. Comprehensive databases may be based on petroleum compositions that have been published in the literature for many reservoirs around the world.

For the presented example, the relative amounts of methane through pentane obtained from mudgas-logs are processed through a computer program that calculates the mole fraction of hexane (f₆), the mole Fraction of heptane+pseudo-component (f₇₊), and the apparent molecular weight of heptane+pseudo-component (MW₇₊).

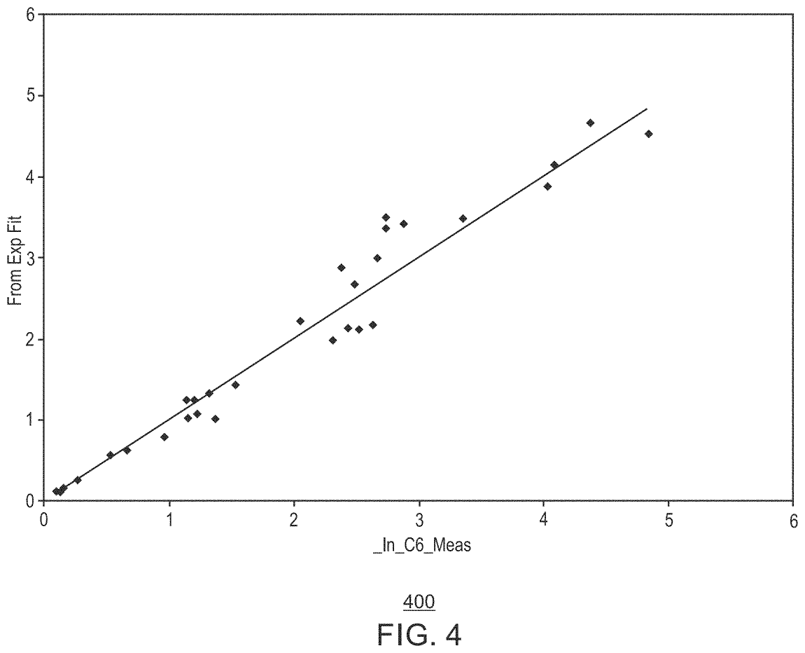

Plots of the predictors (prediction equations) are shown in FIG. 4 to FIG. 6, respectively. If the available database of reservoir fluid compositions also includes other fluid properties (bubble-point pressure and gas-oil-ratio for oil reservoirs, and dew-point pressure and condensate-gas-ratio for gas reservoirs, fluid compressibility, viscosity, fluid density API gravity of produced oil and specific gravity of produced gas) the computer program can used to calculate those properties directly.

FIG. 4 is a plot 400 of the prediction of the mole fraction of hexane from mud log data. The non-parametric or parametric regression analysis, using available computer program for implementation for ACE method, may be used to generate the following equations from the database of petroleum fluid composition described herein.

In each of the following equations (1-9), the left hand side represents the natural log of the transform variable for each molecule. For example, in the first equation, “ln_Ethane_Tr, refers to the natural log of transform for Ethane. The term x on the right hand side of the equation refers to relative amount of ethane in the total mudgas amount reported. Therefore, it is the ratio of ethane molecule ppm to total gas ppm. In each of the equations, x refers to the ratio for the molecule indicated on the left hand side of the equation.

_ln_Ethane_Tr=2.430E−01x\hat{ }2+1.642x+2.337 (1)

_ln_iButane_Tr=−3.893E−02x\hat{ }2+5.621E−02x+9.759E−01 (2)

_ln_iPentanes_Tr=−5.541E−02x\hat{ }2−7.824E−01x−2.314 (3)

_ln_Methane_Tr=7.424E−01x\hat{ }2+3.454x+1.224 (4)

_ln_nButane_Tr=1.164E−01x\hat{ }2+1.348x+3.133 (5)

_ln_nPentane_Tr=−2.153E−02x\hat{ }2+9.459E−01x+4.280 (6)

_ln_Propane_Tr=−3.706E−02x\hat{ }2−6.394E−01x−1.376 (7)

C6_Tr=−9.589E−03x\hat{ }2+1.120E−01x−1.652E−01 (8)

_ln_C6=−7.186E−05SumTr\hat{ }2+1.113SumTr+2.578E−01 (9)

The last equation (9) is the predictor equation to calculate the mole fraction of hexane in the reservoir fluid from the target reservoir. The left hand side of this equation for “ln_C6” refers to the natural log of the mole fraction of hexane in the reservoir fluid from the reservoir at selected depth and “SumTr” refers to the sum of the transforms calculated from the preceding equations. Results of this calculation represents the values on the y-axis of FIG. 4 whereas the x-axis refers to the measured value of hexane mole fraction for the composition used for verification.

It should be noted that the coefficients in each of the above and following equations are specific to the fluid composition database utilized to generate these equations using the ACE computer program implementation. If the fluid composition database is revised by addition or deletion of fluid compositions, the predictor equations need to be regenerated with revised coefficients.

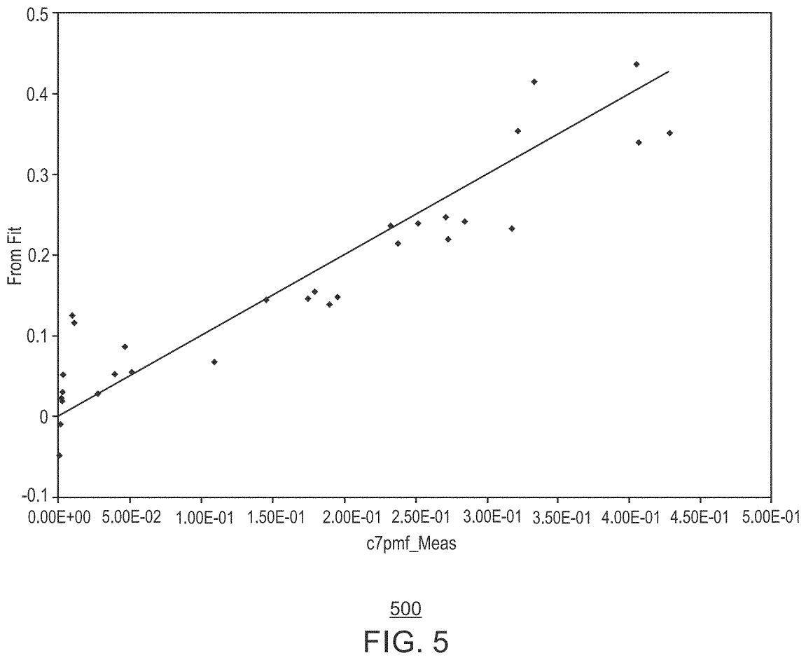

FIG. 5 is a plot 500 of the prediction of the mole fraction of heptane+ from mud log data. In each of the following equations (11-17), the left hand side represents the natural log of the transform variable for each molecule. For example, in the first equation, “ln_Ethane_Tr, refers to the natural log of transform for Ethane. The term x on the right hand side of the equation refers to relative amount of ethane in the total mudgas amount reported. Therefore it is the ratio of ethane molecule ppm to total gas ppm. In each of the following equations, x refers to the ratio for the molecule indicated on the left hand side of the equation.

_ln_Ethane_Tr=−3.867E−01x\hat{ }2−2.611x−3.714 (10)

_ln_iButane_Tr=−8.094E−02x\hat{ }2−6.577E−01x−1.307 (11)

_ln_iPentanes_Tr=1.811E−01x\hat{ }2+1.078x+1.133 (12)

_ln_Methane_Tr=−3.074x\hat{ }2−5.636x−1.666 (13)

_ln_nButane_Tr=1.401E−02x\hat{ }2−4.278E−01x−1.563 (14)

_ln_nPentane_Tr=7.835E−02x\hat{ }2+2.098x+7.246 (15)

_ln_Propane_Tr=−1.878E−01x\hat{ }2−1.042x−1.401 (16)

c7pmf=1.451E−3SumTr\hat{ }2+1.404E−01SumTr+1.587E−01 (17)

The last equation (17) is the predictor equation used to calculate the mole fraction of heptane-plus (C7+) in the reservoir fluid from the target reservoir. The left hand side of this equation, c7pmf, refers to the mole fraction of heptane-plus in the reservoir fluid from the reservoir at selected depth and “SumTr” refers to the sum of the transforms calculated by each of the preceding equations. Results of this calculation represents the values on the y-axis of FIG. 5 whereas the x-axis refers to the measured value of heptane-plus mole fraction for the composition used for verification.

It should be noted that the coefficients in each of the above and following equations are specific to the fluid composition database utilized to generate these equations using the ACE computer program implementation. If the fluid composition database is revised by adding or deleting measured components, the predictor equations need to be regenerated with revised coefficients.

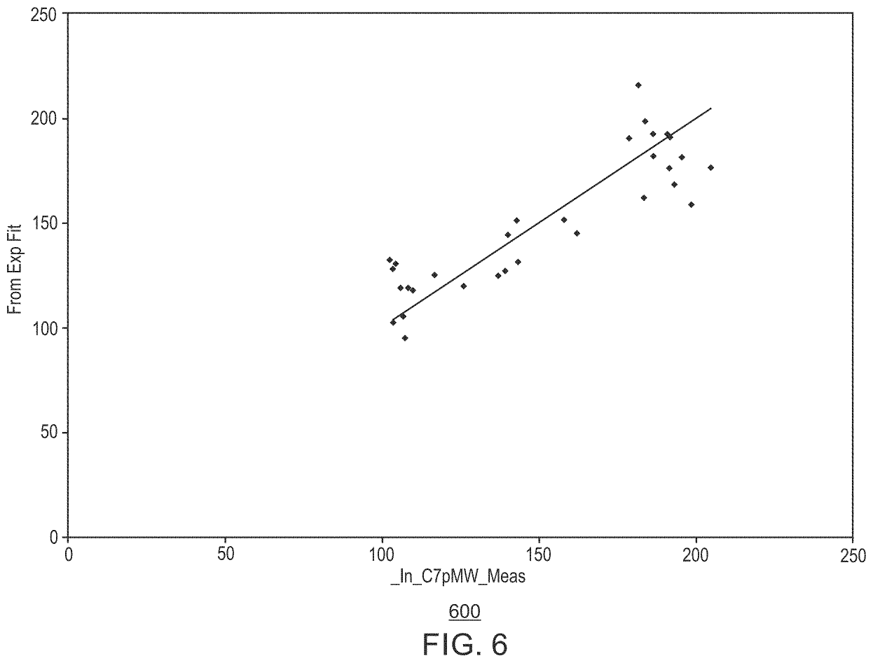

FIG. 6 is a plot 600 of the prediction of the apparent molecular weight of heptane+ from mud log data. In each of the following equations (18-25), the left hand side represents the natural log of the transform variable for each molecule. For example, in the first equation, “ln_Ethane_Tr, refers to the natural log of transform for Ethane. The term x on the right hand side of the equation refers to relative amount of ethane in the total mudgas amount reported. Therefore, it is the ratio of the ethane molecules to total gas molecules. In each of the following equations, x refers to the ratio for the molecule indicated on the left hand side of the equation.

_ln_Ethane_Tr=−1.826x\hat{ }2−8.917x−1.050E+01 (18)

_ln_iButane_Tr=3.263E−02x\hat{ }2+3.219E−01x+7.713E−01 (19)

_ln_iPentanes_Tr=2.168E−01x\hat{ }2+1.556x+2.513 (20)

_ln_Methane_Tr=−6.366x\hat{ }2−5.040x−8.467E−01 (21)

_ln_nButane_Tr=8.556E−02x\hat{ }2+1.303E−01x−5.266E−01 (22)

_ln_nPentane_Tr=5.264E−02x\hat{ }2+1.973x+7.189 (23)

_ln_Propane_Tr=−8.377E−01x\hat{ }2−4.077x−4.805 (24)

_ln_C7pMW=−8.615E−03SumTr\hat{ }2+2.487E−01SumTr+4.995 (25)

The last equation (25) is the predictor equation to calculate the apparent molecular weight of heptane-plus (C7+) in the reservoir fluid from the target reservoir. The left hand side of this equation, _ln_c7MW, refers to the natural log of the apparent molecular weight of heptane-plus in the reservoir fluid from the reservoir at selected depth and “SumTr” refers to the sum of the transforms calculated in the preceding equations. Results of this calculation represents the values on the y-axis of FIG. 6 whereas the x-axis refers to the measured value of the apparent molecular weight of heptane-plus for the composition used for verification.

It should be noted that the coefficients in each of the above and following equations are specific to the fluid composition database utilized to generate these equations using the ACE computer program implementation. If the fluid composition database is revised by addition or deletion of fluid compositions, the predictor equations need to be regenerated with revised coefficients.

Based on the calculated results, the sum of mole fractions of methane to pentane (f₁₋₅) is calculated using Equation 26.

Sum(f₁ to f₅)=1−f₆−f₇₊ (26)

In Equation 1, f₆ refers to C6, calculated as ln_C6 by Equation 9 and plotted in FIG. 4. F₇₊ refers to c7pmf, as calculated by Equation 17 and plotted in FIG. 5.

The relative amounts tabulated in Table 3 are multiplied with the resulting Sum(f_{1 to} f₅) in order to calculate the mole fractions of all necessary components needed to fully define the composition of reservoir fluid as shown in Table 4

As described herein, the full composition as calculated in Table 4, when used along with Equation of State, such as the Peng-Robinson equation of state, or any other suitable equation of state known in the art, is sufficient to calculate other reservoir properties of interest such as the API gravity of oil, a Gas-Oil-Ratio, a Condensate-Gas-Ratio. Such equations of state for hydrocarbon fluid mixtures are known in the art. Further properties for primary and enhanced recovery processes, are calculated using the commercially available implementations of various equations of states using the reservoir fluid composition data calculated herein, such as CMG-WINPROP, PVTSIM and REFPROP (National Institute of Standards and Testing). Examples of these fluid characteristics include Gas-oil-Ratio, Condensate-Gas-Ratio, API gravity of oil, specific gravity of produced gas, etc.

An embodiment described in examples herein provides a method for predicting hydrocarbon composition of a reservoir fluid from mud log data. The method includes generating predictors from an analysis of a database of mud log data, generating predicted mole fractions of a hexane fraction and a heptane+ fraction using the predictors, generating a predicted molecular weight of the heptane+ fraction, and predicting mole fractions of hydrocarbons representing the hydrocarbon composition of the reservoir fluid. The hydrocarbon composition, the predicted molecular weight, the predicted mole fractions or the predictors, or any combinations thereof, are displayed.

In an aspect, the method includes generating the predictors using a nonparametric regression analysis of the database. In an aspect, the method includes generating the predictors using an alternating conditional expression method.

In an aspect, the hydrocarbons representing the hydrocarbon composition include methane, ethane, propane, butane, pentane, hexane, and heptane+.

In an aspect, the method includes collecting the mud log data, and building the database from the mud log data. In an aspect, the method includes using the mole fractions of the hydrocarbons representing the hydrocarbon composition of the reservoir fluid in an equation of state to predict reservoir fluid properties.

In an aspect, the reservoir fluid properties include oil fluid properties. In an aspect, the oil fluid properties include bubble-point pressure, gas-oil-ratio, viscosity, fluid density, or API gravity of produced oil, or any combinations thereof.

In an aspect, the reservoir fluid properties include gas properties. In an aspect, the gas properties include dew-point pressure, condensate-gas-ratio, fluid compressibility, or specific gravity of produced gas, or any combinations thereof.

In an aspect, the method includes using the reservoir fluid properties to design downstream equipment. In an aspect, the method includes using the mole fractions of the hydrocarbons representing the hydrocarbon composition of the reservoir fluid in a reservoir simulation model to predict reservoir properties. In an aspect, the reservoir properties include future production, expected ultimate recovery, or potential additional oil, or any combinations thereof.

Another embodiment described in examples herein provides a system for predicting hydrocarbon composition of a reservoir fluid from mud log data. The system includes a processor and a datastore. The data store includes, a composition database, and a regression engine including instructions that, when executed, direct the processor to analyze the composition database to generate predictors. The data store also includes a predictor store including predictors generated by the regression engine, and a prediction calculator including instructions that, when executed, direct the processor to generate composition predictions. The system includes an output device to provide the predictors, the composition predictions, or both to a user.

In an aspect, the data store includes instructions that, when executed, direct the processor to obtain mud log composition data, and generate the composition database. In an aspect, the datastore includes instructions that, when executed, direct the processor to calculate properties of reservoir fluids from the composition predictions. In an aspect, the instructions include an equation of state.

In an aspect, the datastore includes a reservoir simulation model including instructions that, when executed, direct the processor to model reservoir properties based, at least in part, on the composition predictions. In an aspect, the reservoir properties include future production, expected ultimate recovery, or potential additional oil, or any combinations thereof.

In an aspect, the output device includes a display, a printer, or both. In an aspect, the system includes a network interface controller to couple to data sources for mud log composition data.

Other implementations are also within the scope of the following claims.

TABLE 1
more detailed mole fractions may be reported as shown

| N₂ | CO₂ | H₂S | CH₄ | C₂H₆ | C₃H₈ | i-C₄H₁₀ | n-C₄H₁₀ | l-C₅H₁₂ | n-C₅H₁₂ | C₆H₁₄ | C₇H₁₆ | C₈H₁₈ | C₉H₂₀ | C₁₀H₂₂ | C₁₁H₂₄ | C₁₂H₂₆₊ |
|---|---|---|---|---|---|---|---|---|---|---|---|---|---|---|---|---|
| fN₂ | fC0₂ | fH₂s | f₁ | f₂ | f₃ | fᵢ₄ | fₙ₄ | f₅ | fₙ₅ | f₆ | f₇ | f₈ | f₉ | f₁₀ | f₁₁ | f₁₂₊ |

TABLE 2
common representation of the composition of petroleum reservoir fluids

| N₂ | CO₂ | H₂S | CH₄ | C₂H₆ | C₃H₈ | i-C₄H₁₀ | n-C₄H₁₀ | l-C₅H₁₂ | n-C₅H₁₂ | C₆H₁₄ | C₇+ | MW_{C7+} |
|---|---|---|---|---|---|---|---|---|---|---|---|---|
| f_{N2} | f_{C02} | f_{H2s} | f₁ | f₂ | f₃ | fᵢ₄ | fₙ₄ | f₅ | fₙ₅ | f₆ | f₇₊ | — |

TABLE 3
Relative Amount of Methane to Pentane from Mudgas Log

| Methane | Ethane | Propane | Isobutane | N-butane | Isopentane | N-pentane |
|---|---|---|---|---|---|---|
| 0.708 | 0.151 | 0.070 | 0.11 | 0.029 | 0.008 | 0.023 |

TABLE 4
Calculated Mole Fractions of Components in a Reservoir Fluid

| Methane | Ethane | Propane | Isobutane | N-butane | Isopentane | N-pentane | Hexane | Heptane+ (MW₇₊) |
|---|---|---|---|---|---|---|---|---|
| 0.708* f₁₋₅ | 0.151* f₁₋₅ | 0.070* f₁₋₅ | 0.11* f₁₋₅ | 0.029* f₁₋₅ | 0.008* f₁₋₅ | 0.023* f₁₋₅ | f₆ | F₇ |

What is claimed is:

1. A method for predicting hydrocarbon composition of a reservoir fluid from mud log data, comprising:
generating predictors from an analysis of a database of mud log data;
generating predicted mole fractions of a hexane fraction and a heptane+ fraction using the predictors;
generating a predicted molecular weight of the heptane+ fraction;
predicting mole fractions of hydrocarbons representing the hydrocarbon composition of the reservoir fluid; and
displaying the hydrocarbon composition, the predicted molecular weight, the predicted mole fractions or the predictors, or any combinations thereof.

2. The method of claim 1, comprising generating the predictors using a nonparametric regression analysis of the database.

3. The method of claim 1, comprising generating the predictors using an alternating conditional expression method.

4. The method of claim 1, wherein the hydrocarbons representing the hydrocarbon composition comprise methane, ethane, propane, butane, pentane, hexane, and heptane+.

5. The method of claim 1, comprising:
collecting the mud log data; and
building the database from the mud log data.

6. The method of claim 1, comprising using the mole fractions of the hydrocarbons representing the hydrocarbon composition of the reservoir fluid in an equation of state to predict reservoir fluid properties.

7. The method of claim 6, wherein the reservoir fluid properties comprise oil fluid properties.

8. The method of claim 7, wherein the oil fluid properties comprise bubble-point pressure, gas-oil-ratio, viscosity, fluid density, or API gravity of produced oil, or any combinations thereof.

9. The method of claim 6, wherein the reservoir fluid properties comprise gas properties.

10. The method of claim 9, wherein the gas properties comprise dew-point pressure, condensate-gas-ratio, fluid compressibility, or specific gravity of produced gas, or any combinations thereof.

11. The method of claim 6, comprising using the reservoir fluid properties to design downstream equipment.

12. The method of claim 1, comprising using the mole fractions of the hydrocarbons representing the hydrocarbon composition of the reservoir fluid in a reservoir simulation model to predict reservoir properties.

13. The method of claim 12, wherein the reservoir properties comprise future production, expected ultimate recovery, or potential additional oil, or any combinations thereof.

14. A system for predicting hydrocarbon composition of a reservoir fluid from mud log data, comprising:
a processor;
a datastore, comprising:
a composition database;
a regression engine comprising instructions that, when executed, direct the processor to analyze the composition database to generate predictors;
a predictor store comprising predictors generated by the regression engine; and
a prediction calculator comprising instructions that, when executed, direct the processor to generate composition predictions; and
an output device to provide the predictors, the composition predictions, or both to a user.

15. The system of claim 14, wherein the data store comprises instructions that, when executed, direct the processor to:
obtain mud log composition data; and
generate the composition database.

16. The system of claim 14, wherein the datastore comprises instructions that, when executed, direct the processor to calculate properties of reservoir fluids from the composition predictions.

17. The system of claim 16, wherein the instructions comprise an equation of state.

18. The system of claim 14, wherein the datastore comprises a reservoir simulation model comprising instructions that, when executed, direct the processor to model reservoir properties based, at least in part, on the composition predictions.

19. The system of claim 18, wherein the reservoir properties comprise future production, expected ultimate recovery, or potential additional oil, or any combinations thereof.

20. The system of claim 14, wherein the output device comprises a display, a printer, or both.

21. The system of claim 14, comprising a network interface controller to couple to data sources for mud log composition data.
